(19) United States
(12) Patent Application Publication
(10) Pub. No.: US 2017/0113967 A1
(43) Pub. Date: Apr. 27, 2017

(54) STRENGTHENED, ANTIMICROBIAL GLASS ARTICLES AND METHODS FOR MAKING THE SAME

(71) Applicant: CORNING INCORPORATED, Corning, NY (US)

(72) Inventors: Christy Lynn Chapman, Painted Post, NY (US); Sinue Gomez, Corning, NY (US)

(21) Appl. No.: 15/297,355

(22) Filed: Oct. 19, 2016

Related U.S. Application Data
(60) Provisional application No. 62/244,396, filed on Oct. 21, 2015.

(51) Int. Cl. C03C 21/00; H05K 5/00; H05K 5/03; C03C 4/00

(52) U.S. Cl. CPC C03C 21/005; C03C 21/002; C03C 4/00; H05K 5/0017; H05K 5/03; C03C 2204/02

(57) ABSTRACT

A method of making a strengthened, antimicrobial glass article that includes: providing a glass article comprising a primary surface and ion-exchangeable alkali metal ions; providing a first molten salt bath comprising 60 to 95 wt. % alkali metal ions that are larger in size than the ion-exchangeable alkali metal ions; providing a second molten salt bath comprising alkali metal ions and about 1 to 10 wt. % silver ions; submersing the glass article in the first bath to exchange a portion of the ion-exchangeable alkali metal ions with a portion of the ions in the first bath to define a compressive stress layer extending from the primary surface to a DOL; and submersing the glass article in the second bath to exchange alkali metal ions in the compressive stress layer with a portion of the silver ions in the second bath to impart an antimicrobial property at the primary surface.

### CROSS-REFERENCE TO RELATED APPLICATIONS

This application claims the benefit of priority under 35 U.S.C. §119 of U.S. Provisional Application Ser. No. 62/244,396 filed on Oct. 21, 2015, the content of which is relied upon and incorporated herein by reference in its entirety.

### TECHNICAL FIELD

The present invention generally relates to strengthened, antimicrobial glass articles and methods for making them for various applications including but not limited to touch screens for various electronic devices, e.g., mobile phones, laptop computers, book readers, hand-held video gaming systems, automated teller machines, elevator displays, electronic signage.

### BACKGROUND

Touch-activated or -interactive devices, such as screen surfaces (e.g., surfaces of electronic devices having user-interactive capabilities that are activated by touching specific portions of the surfaces), have become increasingly more prevalent in the electronic device industry. In general, these surfaces should exhibit high optical transmission, low haze, and high durability, among other features. As the extent to which the touch screen-based interactions between a user and a device increases, so too does the likelihood of the surface harboring microorganisms (e.g., bacteria, fungi, viruses, and the like) that can be transferred from user to user.

To minimize the presence of microbes on glass, “antimicrobial” properties have been imparted to a variety of glass articles. Such antimicrobial glass articles, regardless of whether they are used as screen surfaces of touch-activated devices or in other applications, still need to exhibit high strength (including high average flexural strength). In addition, such antimicrobial articles should also be resistant to color changes when exposed to elevated temperatures, humidity, reactive environments and the like. These harsh conditions can occur during fabrication or processing of the glass articles, or during ordinary use of the articles. In certain cases, this discoloration can render a glass article unsightly. Further, excessive discoloration ultimately can lead to the glass article becoming unsuitable for its intended purpose

Various processes, including ion-exchange baths, can be used to “chemically” strengthen glass articles. Ion-exchange bath processes, for example, can be used to increase the strength of a glass article by developing a compressive stress (“CS”) layer in a surface region of the article. For example, metal ions in the surface region of an as-produced glass article can be replaced by larger metal ions through ion-exchange processes. These larger metal ions create a local stress field, thereby generating the beneficial compressive stress layer.

Similarly, ion-exchange processes can be used to impart antimicrobial properties in a glass article by injecting certain metal ions, e.g. Ag⁺, into the surface of the article. The Ag⁺ ions interact with microbes at the surface of the glass article to kill them or otherwise inhibit their growth. However, the presence of these Ag⁺ ions and/or the processes used to exchange them in a glass article can negatively influence other characteristics of the glass articles (e.g., the mechanical properties of the articles). Further, Ag⁺ ion precursors are relatively expensive materials to obtain and process.

Accordingly, there is a need for new processes for efficiently making strengthened, antimicrobial glass articles with antimicrobial capabilities that do not significantly alter other performance attributes of these articles.

### SUMMARY

According to a first aspect, a method of making a strengthened, antimicrobial glass article is provided. The method includes the steps: providing a glass article comprising a primary surface and a plurality of ion-exchangeable alkali metal ions; providing a first molten salt bath comprising a mixture of ion-exchanging alkali metal ions, the mixture having about 60 to 95 wt. % alkali metal ions that are larger in size than the ion-exchangeable alkali metal ions; providing a second molten salt bath comprising a mixture of ion-exchanging alkali metal ions and about 1 to 10 wt. % silver ions; submersing the glass article in the first bath to exchange a portion of the plurality of ion-exchangeable alkali metal ions in the glass article with a portion of the mixture of ion-exchanging alkali metal ions in the first bath to define a compressive stress layer extending from the primary surface to a depth-of-layer (DOL) in the glass article; and submersing the glass article in the second bath to exchange a portion of the alkali metal ions in the compressive stress layer with a portion of the silver ions in the second bath to impart an antimicrobial property at the primary surface of the glass article.

In a second aspect according to the first aspect, wherein the first molten salt bath comprises a mixture of about 60 to 95 wt. % KNO₃ and a balance of NaNO₃.

In a third aspect according to the first or second aspects, wherein the second molten salt bath comprises a mixture of KNO₃ and 1 to 10 wt. % AgNO₃.

In a fourth aspect according to any one of the first through third aspects, wherein the submersing the glass article in the first bath can be conducted for a duration between 3 hours and 16 hours with the first bath held between 390° C. and about 470° C.

In a fifth aspect according to any one of the first through fourth aspects, wherein the submersing the glass article in the second bath can be conducted for a duration of about 5 minutes to about 60 minutes with the second bath held between 325° C. and about 400° C.

In a sixth aspect according to any one of the first through fifth aspects, wherein the DOL is about 70 μm or greater in the glass article.

In a seventh aspect according to any one of the first through sixth aspects, wherein the compressive stress layer is characterized by a peak compressive stress of 700 MPa or greater.

In an eighth aspect according to any one of the first through seventh aspects, wherein the antimicrobial property of the strengthened, antimicrobial glass article comprises a log kill of 1.5 or greater, 2.0 or greater, and, in some cases, 2.5 or greater for S. aureus bacteria as tested under a Dry Test Protocol.

In a ninth aspect according to any one of the first through eighth aspects, wherein the antimicrobial property comprises a log kill of 1.5 or greater for S. aureus bacteria as tested under a Dry Test Protocol after deposition of a fingerprint- or smudge-resistant coating on the primary surface of the glass article.

In a tenth aspect according to any one of the first through ninth aspects, wherein the second molten salt bath comprises a mixture of KNO₃ and 2 to 5 wt. % AgNO₃, and further wherein the antimicrobial property comprises a log kill of 2.5 or greater for S. aureus bacteria as tested under a Dry Test Protocol.

In an eleventh aspect, a strengthened, antimicrobial glass article is provided that includes: a glass article comprising a primary surface and a thickness from about 0.5 mm to 2 mm; a compressive stress layer extending from the primary surface of the glass article to a first depth-of-layer (DOL) in the glass article; and an antimicrobial region comprising a plurality of silver ions extending from the primary surface to a second DOL in the glass article. The primary surface of the glass article has a concentration of silver ions that ranges from about 2 mol % to about 20 mol % and the compressive stress layer is characterized by a peak compressive stress of 700 MPa or greater. Further, the antimicrobial region comprises an antimicrobial property at the primary surface characterized by a log kill of 2 or greater for S. aureus bacteria as tested under a Dry Test Protocol.

In a twelfth aspect according to the eleventh aspect, wherein the primary surface of the glass article has a concentration of silver ions that ranges from about 4 mol % to about 15 mol %.

In a thirteenth aspect according to the eleventh or twelfth aspect, wherein the first DOL is about 70 μm or greater in the glass article.

In a fourteenth aspect according to any one of the eleventh through thirteenth aspects, wherein the antimicrobial region comprises an antimicrobial property at the primary surface characterized by a log kill of 2.5 or greater for S. aureus bacteria as tested under a Dry Test Protocol.

In a fifteenth aspect according to any one of the eleventh through fourteenth aspects, wherein the antimicrobial region comprises an antimicrobial property at the primary surface characterized by a log kill of 3.0 or greater for S. aureus bacteria as tested under a Dry Test Protocol.

In a sixteenth aspect according to any one of the eleventh through fifteenth aspects, wherein the antimicrobial region comprises an antimicrobial property in proximity to the primary surface characterized by a log kill of 2 or greater for S. aureus bacteria as tested under a Dry Test Protocol after deposition of a fingerprint- or smudge-resistant coating on the primary surface of the glass article.

In a seventeenth aspect, a method of making a strengthened, antimicrobial glass article is provided. The method includes the steps: providing a glass article comprising a primary surface and a plurality of ion-exchangeable alkali metal ions; providing a first molten salt bath comprising a mixture of ion-exchanging alkali metal ions between about 420° C. and about 460° C., the mixture having about 60 to 95 wt. % K⁺ ions and a balance of Na⁺ ions; providing a second molten salt bath comprising a mixture of about 1 to 10 wt. % Ag⁺ ions and a balance of K⁺ ions between about 325° C. and about 400° C.; submersing the glass article in the first bath for about 5 hours to 10 hours to exchange a portion of the plurality of ion-exchangeable alkali metal ions in the glass article with a portion of the mixture of K⁺ and Na⁺ ions in the first bath to define a compressive stress layer extending from the primary surface to a depth-of-layer (DOL) in the glass article; and submersing the glass article in the second bath for about 15 minutes and 60 minutes to exchange a portion of the alkali metal ions in the compressive stress layer with a portion of the Ag⁺ ions in the second bath to impart an antimicrobial property at the primary surface of the glass article. The antimicrobial property comprises a log kill of 1.5 or greater for S. aureus bacteria as tested under a Dry Test Protocol. Further, the compressive stress layer is characterized by a peak compressive stress of 600 MPa or greater.

In an eighteenth aspect according to the seventeenth aspect, wherein the mixture of ion-exchanging alkali metal ions of the first molten salt bath is set at about 450° C. and the mixture of about 1 to 10 wt. % Ag⁺ ions and a balance of K⁺ ions of the second molten salt bath is set between 380° C. and 400° C.

In a nineteenth aspect according to the seventeenth or eighteenth aspects, wherein the second molten salt bath comprises a mixture of about 1 to 5 wt % Ag⁺ ions and a balance of K⁺ ions and the compressive stress layer is characterized by a peak compressive stress of 700 MPa or greater.

In a twentieth aspect according to any one of the seventeenth through nineteenth aspects, wherein the antimicrobial property comprises a log kill of 2.5 or greater for S. aureus bacteria as tested under a Dry Test Protocol.

In a twenty-first aspect a device is provided including a housing having front, back, and side surfaces; electrical components that are at least partially inside the housing; a display at or adjacent to the front surface of the housing; and a cover substrate disposed over the display, wherein the cover substrate comprises the strengthened, antimicrobial glass article of any one of the eleventh through sixteenth aspects.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiments, and together with the description serve to explain principles and operation of the various embodiments.

### BRIEF DESCRIPTION OF THE DRAWINGS

FIG. 1 is a schematic of a method of making a strengthened, antimicrobial glass article according to an aspect of the disclosure.

FIG. 1A is a schematic of a strengthened, antimicrobial glass article according to an aspect of the disclosure.

FIG. 2 is a plot of compressive stress measurements obtained on strengthened glass articles as a function of sodium ion concentration in a first molten salt bath taken before and after a second molten salt bath immersion with potassium ions according to an aspect of the disclosure.

FIG. 3A is a plot of compressive stress measurements as a function of depth obtained on glass articles subjected to various Ag⁺ ion concentrations in a second molten salt bath immersion step according to an aspect of the disclosure.

FIG. 3B is a plot of Ag⁺ ion concentration as a function of depth in glass articles subjected to various Ag⁺ ion concentrations in a second molten salt bath immersion step according to an aspect of the disclosure.

FIG. 4 is a plot of Ag⁺ ion concentration as a function of depth in glass articles subjected to various second molten salt bath immersion step time and temperature conditions according to an aspect of the disclosure.

FIG. 5 is a plot of Ag⁺ ion surface concentration as a function of Ag⁺ ion bath concentration for glass articles subjected to various first and second molten salt bath compositions in respective first and second immersion steps according to an aspect of the disclosure.

FIG. 6 is a plot depicting the results from antimicrobial testing of strengthened, antimicrobial glass articles, with and without a fingerprint-resistant surface coating, subjected to various Ag⁺ ion concentrations in a second molten salt bath immersion step according to an aspect of the disclosure.

FIG. 7 is a plot of four-point bend strength values from strengthened, antimicrobial glass articles subjected to various first and second molten salt bath compositions according to an aspect of the disclosure.

FIG. 8 is a plot of peak load failure and compressive stress values for glass articles as a function of Ag⁺ ion bath concentration in a second molten salt bath according to an aspect of the disclosure.

FIG. 9A is a plot of optical transmissivity as a function of wavelength for strengthened, antimicrobial glass articles as a function of Ag⁺ ion bath concentration in a second molten salt bath according to an aspect of the disclosure.

FIG. 9B is a plot of the a* and b* color parameters as measured from exposure to a D65 illumination source for strengthened, antimicrobial glass articles as a function of Ag⁺ ion bath concentration in a second molten salt bath according to an aspect of the disclosure.

FIG. 10A is a plan view of an exemplary electronic device incorporating any of the strengthened, antimicrobial glass articles disclosed herein.

FIG. 10B is a perspective view of the exemplary electronic device of FIG. 10A.

### DETAILED DESCRIPTION

Reference will now be made in detail to the present preferred embodiments, examples of which are illustrated in the accompanying drawings. Whenever possible, the same reference numerals will be used throughout the drawings to refer to the same or like parts.

Discussed herein are new methods for making strengthened, antimicrobial glass articles. The methods generally involve the use of a dual-ion exchange process (“DIOX”). One ion exchange step is arranged to strengthen the glass article via exposure of the glass article to a first molten salt bath. The other step is configured to impart antimicrobial properties in the glass article via exposure of the glass article to a second molten salt bath.

Without being bound by theory, it is believed that a compressive stress layer that develops from ion exchange processes can impact the overall strength level of antimicrobial glass articles. Techniques for measuring compressive stress levels as a function of depth in antimicrobial glass articles are outlined in U.S. Provisional Patent Application Nos. 61/835,823, filed on Jun. 17, 2013, and 61/860,560, filed on Jul. 31, 2013, hereby incorporated by reference. U.S. Pat. No. 9,109,881 claims priority to each of the aforementioned provisional patent applications and is hereby incorporated by reference in its entirety.

In view of the foregoing need for new processes for efficiently making strengthened, antimicrobial glass articles, methods for making glass articles with antimicrobial properties and strength enhancements are outlined in the disclosure. In some aspects, methods for making such glass articles are provided that seek to minimize the quantity of Ag⁺ ion precursors used in the process without significant detriment to antimicrobial properties. In other aspects, methods for making glass articles are provided that seek to maximize the quantity of Ag⁺ ions imparted into the glass articles without significant degradation in the mechanical and/or optical properties of the articles.

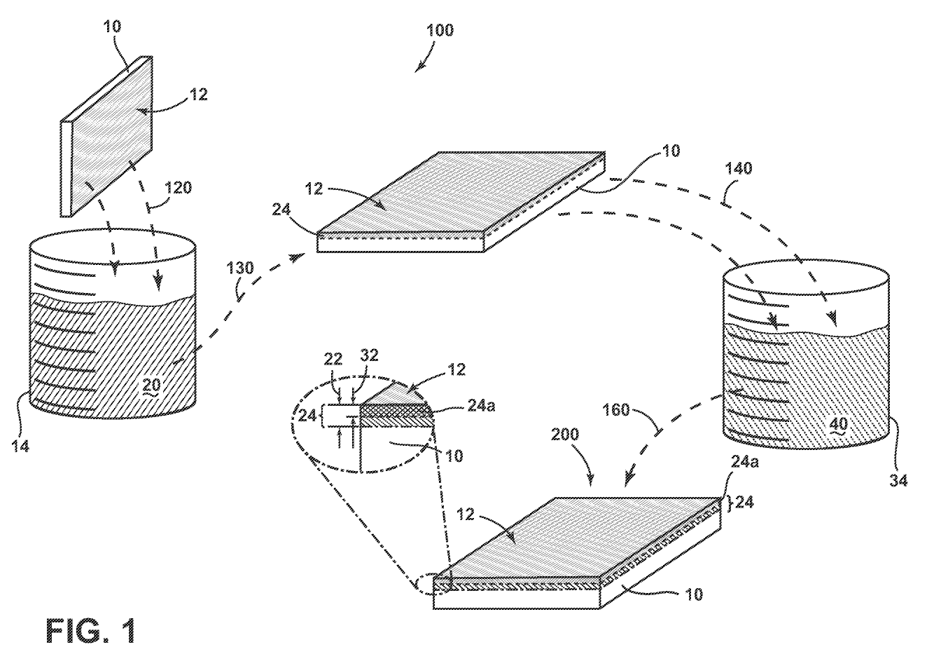

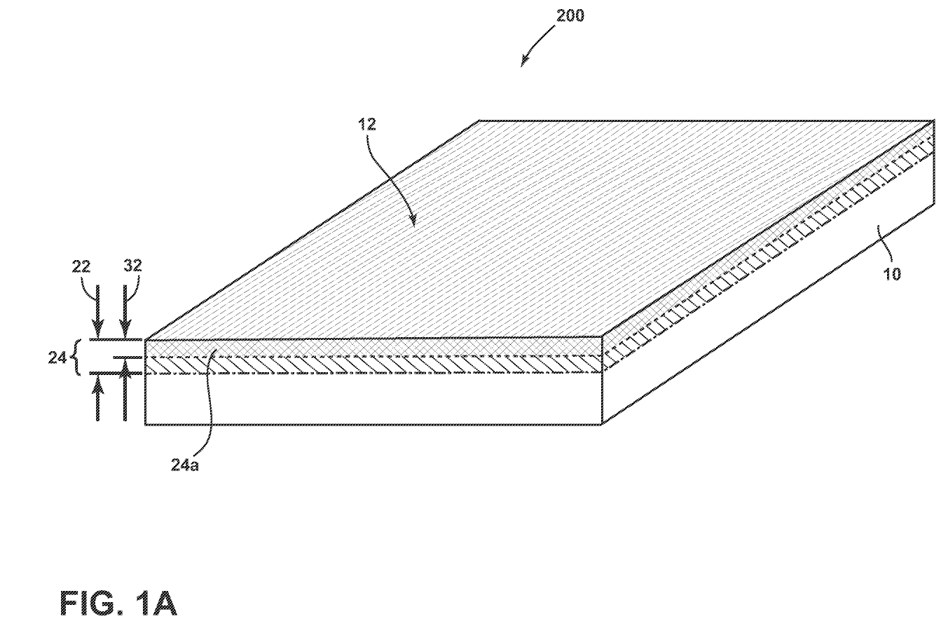

Referring to FIG. 1, a method 100 of making a strengthened, antimicrobial glass article 200 is provided. In the method 100, a glass article 10 is employed having a primary surface 12 and a plurality of ion-exchangeable metal ions. As shown in FIG. 1, glass article 10 possesses other exterior surfaces in addition to primary surface 12. In an exemplary embodiment, glass article 10 can comprise a silicate composition having ion-exchangeable metal ions. The metal ions are exchangeable in the sense that exposure of the glass article 10 and primary surface 12 to a bath containing other metal ions can result in the exchange of some of the metal ions in the glass article 10 with metal ions from the bath. In one or more embodiments, a compressive stress is created by this ion exchange process in which a plurality of first metal ions in glass article 10, and specifically the primary surface 12, are exchanged with a plurality of second metal ions (having an ionic radius larger than the plurality of first metal ions) so that a region of the glass article 10 comprises the plurality of the second metal ions. The presence of the larger second metal ions in this region creates the compressive stress in the region. The first metal ions may be alkali metal ions such as lithium, sodium, potassium, and rubidium. The second metal ions may be alkali metal ions such as sodium, potassium, rubidium, and cesium, with the proviso that the second alkali metal ion has an ionic radius greater than the ionic radius of the first alkali metal ion.

Glass article 10 can comprise various glass compositions. The choice of glass used for the glass article 10 is not limited to a particular composition, as antimicrobial properties can be obtained with enhanced strength using a variety of glass compositions. For example, the composition chosen can be any of a wide range of silicate, borosilicate, aluminosilicate, or boroaluminosilicate glass compositions, which optionally can comprise one or more alkali and/or alkaline earth modifiers.

By way of illustration, one family of compositions that may be employed in glass article 10 includes those having at least one of aluminum oxide or boron oxide and at least one of an alkali metal oxide or an alkali earth metal oxide, wherein ˜15 mol % (R₂O+R′O—Al₂O₃—ZrO₂)—B₂O₃≦4 mol %, where R can be Li, Na, K, Rb, and/or Cs, and R′ can be Mg, Ca, Sr, and/or Ba. One subset of this family of compositions includes from about 62 mol % to about 70 mol % SiO₂; from 0 mol % to about 18 mol % Al₂O₃; from 0 mol % to about 10 mol % B₂O₃; from 0 mol % to about 15 mol % Li₂O; from 0 mol % to about 20 mol % Na₂O; from 0 mol % to about 18 mol % K₂O; from 0 mol % to about 17 mol % MgO; from 0 mol % to about 18 mol % CaO; and from 0 mol % to about 5 mol % ZrO₂. Such glasses are described more fully in U.S. patent application Ser. No. 12/277,573, filed Nov. 25, 2008 (now U.S. Pat. No. 8,969,226), each of which is hereby incorporated by reference in its entirety as if fully set forth below.

Another illustrative family of compositions that may be employed in glass article 10 includes those having at least 50 mol % SiO₂ and at least one modifier selected from the group consisting of alkali metal oxides and alkaline earth metal oxides, wherein [(Al₂O₃ (mol %)+B₂O₃(mol %))/(Σ alkali metal modifiers (mol %))]>1. One subset of this family includes from 50 mol % to about 72 mol % SiO₂; from about 9 mol % to about 17 mol % Al₂O₃; from about 2 mol % to about 12 mol % B₂O₃; from about 8 mol % to about 16 mol % Na₂O; and from 0 mol % to about 4 mol % K₂O. Such glasses are described in more fully in U.S. patent application Ser. No. 12/858,490, filed Aug. 18, 2010 (now U.S. Pat. No. 8,586,492), each of which is hereby incorporated by reference in its entirety as if fully set forth below.

Yet another illustrative family of compositions that may be employed in glass article 10 includes those having SiO₂, Al₂O₃, P₂O₅, and at least one alkali metal oxide (R20), wherein 0.75≦[(P₂O₅(mol %)+R₂O(mol %))/M₂O₃ (mol %)]≦1.2, where M₂O₃=Al₂O₃+B₂O₃. One subset of this family of compositions includes from about 40 mol % to about 70 mol % SiO₂; from 0 mol % to about 28 mol % B₂O₃; from 0 mol % to about 28 mol % Al₂O₃; from about 1 mol % to about 14 mol % P₂O₅; and from about 12 mol % to about 16 mol % R₂O. Another subset of this family of compositions includes from about 40 to about 64 mol % SiO₂; from 0 mol % to about 8 mol % B₂O₃; from about 16 mol % to about 28 mol % Al₂O₃; from about 2 mol % to about 12 mol % P₂O₅; and from about 12 mol % to about 16 mol % R₂O. Such glasses are described more fully in U.S. patent application Ser. No. 13/305,271, filed Nov. 28, 2011 (now U.S. Pat. No. 9,346,703), each of which is hereby incorporated by reference in its entirety as if fully set forth below.

Yet another illustrative family of compositions that can be employed in glass article 10 includes those having at least about 4 mol % P₂O₅, wherein (M₂O₃(mol %)/RₓO(mol %))<1, wherein M₂O₃=Al₂O₃+B₂O₃, and wherein RₓO is the sum of monovalent and divalent cation oxides present in the glass. The monovalent and divalent cation oxides can be selected from the group consisting of Li₂O, Na₂O, K₂O, Rb₂O, Cs₂O, MgO, CaO, SrO, BaO, and ZnO. One subset of this family of compositions includes glasses having 0 mol % B₂O₃. Such glasses are more fully described in U.S. Provisional Patent Application No. 61/560,434, filed on Nov. 16, 2011 (now U.S. Pat. No. 8,765,262), the content of each is hereby incorporated by reference in its entirety as if fully set forth below.

Still another illustrative family of compositions that can be employed in glass article 10 includes those having Al₂O₃, B₂O₃, alkali metal oxides, and contains boron cations having three-fold coordination. When ion exchanged, these glasses can have a Vickers crack initiation threshold of at least about 30 kilograms force (kgf). One subset of this family of compositions includes at least about 50 mol % SiO₂; at least about 10 mol % R₂O, wherein R₂O comprises Na₂O; Al₂O₃, wherein −0.5 mol % Al₂O₃(mol %)−R₂O(mol %)≦2 mol %; and B₂O₃, and wherein B₂O₃(mol %)−(R₂O(mol %)−Al₂O₃(mol %))≧4.5 mol %. Another subset of this family of compositions includes at least about 50 mol % SiO₂, from about 9 mol % to about 22 mol % Al₂O₃; from about 4.5 mol % to about 10 mol % B₂O₃; from about 10 mol % to about 20 mol % Na₂O; from 0 mol % to about 5 mol % K₂O; at least about 0.1 mol % MgO and/or ZnO, wherein 0<MgO+ZnO≦6 mol %; and, optionally, at least one of CaO, BaO, and SrO, wherein 0 mol %≦CaO+SrO+BaO≦2 mol %. Such glasses are more fully described in U.S. Provisional Patent Application No. 61/653,485, filed May 31, 2012 (now published as U.S. Pub. No. 2014/0106172), the content of each is incorporated herein by reference in its entirety as if fully set forth below.

The glass article 10 can adopt a variety of physical forms, including a glass substrate. That is, from a cross-sectional perspective, the glass article 10, when configured as a substrate, can be flat or planar, or it can be curved and/or sharply-bent. Similarly, glass article 10 can be a single unitary object, a multi-layered structure, or a laminate.

The glass article 10 may also be combined with a layer, such as a functional layer, disposed on a surface thereof. For example, the layer can include a reflection-resistant coating, a glare-resistant coating, a fingerprint-resistant coating, a smudge-resistant coating, a color-providing composition, an environmental barrier coating, or an electrically conductive coating. For example, the glass article 10 can be coated with a Dow Corning® 2634 fluorosilane abrasion- and fingerprint-resistant coating in some implementations.

Referring again to FIG. 1, the method 100 of making a strengthened, antimicrobial glass article 200 employs a first molten salt bath 20 contained within a vessel 14. The strengthening bath 20 contains a plurality of ion-exchanging metal ions. In some embodiments, for example, bath 20 may contain a plurality of potassium ions that are larger in size than ion-exchangeable ions, such as sodium, contained in the glass article 10. These ion-exchanging ions contained in the bath 20 will preferentially exchange with ion-exchangeable ions in the glass article 10 when the article 10 is submersed in the bath 20. In certain aspects of the method, the first molten salt bath 20 comprises a molten KNO₃ bath at a concentration between about 95 and 60 wt. % with one or more additives. In certain aspects of the method, the first molten salt bath 20 comprises a molten KNO₃ bath at a concentration between about 95 and 60 wt. % with a balance of NaNO₃ as the additive. More generally, the bath 20 is sufficiently heated to a temperature to ensure that the KNO₃ and any additives remain in a molten state during processing of the glass article 10. In certain aspects, the first molten salt bath 20 may also include the combination of KNO₃ and one or both of NaNO₃ and LiNO₃.

Still referring to FIG. 1, the method 100 of making a strengthened, antimicrobial glass article 200 includes a step 120 for submersing the glass article 10 into the first molten salt bath 20. Upon submersion into the bath 20, a portion of the plurality of the ion-exchangeable ions (e.g., Na⁺ ions) in the glass article 10 are exchanged with a portion of the plurality of the ion-exchanging ions (e.g., K⁺ ions) contained in the first molten salt bath 20. According to some aspects, the submersion step 120 is conducted for a predetermined time based on the composition of the bath 20, temperature of the bath 20, composition of the glass article 10 and/or the desired concentration of the ion-exchanging ions in the glass article 10. In certain implementations, the step 120 for submersing the glass article 10 in the first molten salt bath 20 is conducted for a duration between 1 hour and 20 hours with the first bath being held at a temperature ranging from about 375° C. to about 480° C., and all values therebetween. According to some aspects, the duration is between about 3 hours and 16 hours and the first molten salt bath is held at a temperature ranging from about 390° C. to about 470° C. In one implementation, the duration is between about 7 and 8 hours and the first molten bath 20 is held at a temperature ranging from about 440° C. to about 460° C.

After the submersion step 120 is completed, a washing step 130 can be conducted in certain aspects of the method 100 to remove material from the bath 20 remaining on the surfaces of glass article 10, including the primary surface 12. Deionized water, for example, can be used in the washing step 130 to remove material from the bath 20 on the surfaces of the glass article 10, including primary surface 12. Other media may also be employed for washing the surfaces of the glass article 10 provided that the media are selected to avoid any reactions with material from the bath 20 and/or the glass composition of the glass article 10.

As the ion-exchanging ions from the first molten salt bath 20 are distributed into the glass article 10 at the expense of the ion-exchangeable ions originally in the glass article 10, a compressive stress layer 24 develops in the glass article 10. The compressive stress layer 24 extends from the primary surface 12 to a depth-of-layer (DOL) 22 in the glass article 10. In general, an appreciable concentration of the ion-exchanging ions from the first molten salt bath 20 (e.g., K⁺ ions) exists in the compressive stress layer 24 after the submersion and cleaning steps 120 and 130, respectively. These ion-exchanging ions are generally larger than the ion-exchangeable ions (e.g., Na⁺ ions), thereby increasing the compressive stress level in the layer 24 within the glass article 10. In addition, the amount of compressive stress (“CS”) associated with the compressive stress layer 24 and the DOL 22 can each be varied (by virtue of the conditions of the submersion step 120, for example) based on the intended use of the glass article 10. In some embodiments, the CS level in the compressive stress layer 24 and the DOL 22 are controlled such that tensile stresses generated within the glass article 10 as a result of the compressive stress layer 24 do not become excessive to the point of rendering the glass article 10 frangible. In some embodiments, the CS level in the layer 24 may be about 500 MPa or greater. For example, the CS level in the layer 24 may be up to about 600 MPa, up to about 700 MPa, up to about 800 MPa, up to about 900 MPa, or even up to about 1000 MPa, and all values therebetween. The DOL 22 of the layer 24 may be about 15 μm or greater. In some instances, the DOL may be in the range from about 15 μm to about 100 μm, from about 20 μm to about 90 μm, from about 30 μm to about 80 μm, and all values therebetween. In a preferred aspect, the DOL 22 of the layer 24 is set between about 15 μm and about 70 μm.

Referring again to FIG. 1, the method 100 of making a strengthened, antimicrobial glass article 200 additionally employs a second molten salt bath 40 contained in a vessel 34 that comprises a plurality of metal ions that can provide an antimicrobial effect. In some embodiments, the second molten salt bath 40 includes a plurality of silver ions, each of which can provide an antimicrobial effect; and a plurality of ion-exchanging ions consistent with those present in the first molten salt bath 20 (e.g., K⁺ ions, Na⁺ ions). According to an exemplary embodiment, the bath 40 can possess a plurality of silver ions derived from molten AgNO₃ at a bath concentration of about 1% to 10% by weight. According to another exemplary embodiment, the bath 40 possesses a plurality of silver ions derived from molten AgNO₃ at a bath concentration of about 0.5%, 1%, 2%, 3%, 4%, 5%, 6%, 7%, 8%, 9%, or about 10% by weight, and all values therebetween, and a balance of molten KNO₃. In a further embodiment, the antimicrobial bath 40 comprises about 1% to about 5% by weight molten AgNO₃ with a balance of molten KNO₃.

According to some embodiments, the second molten salt bath 40 can be set at a temperature ranging from about 300° C. to about 400° C., and all values therebetween. Preferably, the second molten salt bath 40 is set at a temperature ranging from about 325° C. to about 400° C. In some embodiments of the method 100 for making a strengthened, antimicrobial glass article 200, the second molten salt bath 40 is set at a temperature of about 330° C., about 350° C., about 370° C., or about 390° C.

Referring further to FIG. 1, the method 100 of making a strengthened, antimicrobial glass article 200 also includes a step 140 for submersing the glass article 10 in the antimicrobial bath 40 to exchange a portion of the ion-exchangeable (e.g., Na⁺ ions) and the ion-exchanging metal ions (e.g., K⁺ ions) in the remaining compressive stress layer 24b with a portion of the plurality of silver metal ions in the antimicrobial bath 40 to impart an antimicrobial property in the glass article 10. The presence of the KNO₃ constituents in the bath 40 helps prevent a significant quantity of strength-enhancing K⁺ ions from being removed from the remaining compressive stress layer 24b in the glass article 10 during the submersion step 140.

In some embodiments of method 100, the step 140 for submersing the glass article 10 in the second molten salt bath 40 is controlled to a duration of at least approximately 5 minutes up to about 60 minutes, and all values therebetween. More particularly, the duration is set to time that is sufficient to impart antimicrobial ions (e.g., Ag⁺ ions) into the glass article 10 for the desired antimicrobial properties associated with the article 10. In certain aspects of the method 100, the duration of the submersion step 140 is set to about 15 minutes, about 30 minutes, or about 45 minutes.

According to some embodiments of the method 100, Ag⁺ ions are imparted into the primary surface 12 of the glass article 10 at a concentration of about 1 mol % to about 20 mol % in step 140 to form an antimicrobial region 24a to a antimicrobial region DOL 32. In further embodiments, Ag⁺ ions are imparted into the antimicrobial region 24a at a surface concentration (e.g., at primary surface 12) of up to about 1 mol %, 2 mol %, 3 mol %, 4 mol %, 5 mol %, 6 mol %, 7 mol %, 8 mol %, 9 mol %, 10 mol %, 11 mol %, 12 mol %, 13 mol %, 14 mol %, 15 mol %, 16 mol %, 17 mol %, 18 mol %, 19 mol %, and 20 mol %, and all values therebetween. The duration of the step 140 is controlled based on the composition and temperature of bath 40, the composition of the glass article 10, and the desired antimicrobial properties associated with the antimicrobial region 24a and the primary surface 12. In some aspects, the DOL 32 associated with the antimicrobial region 24a is from about 1 microns to about 30 microns, and all values therebetween. Without being bound by theory, it is believed that the concentration of the Ag⁺ ions at the primary surface 12 or within a few microns of the surface (e.g., above the DOL 32) significantly influences the overall antimicrobial efficacy of the antimicrobial region 24a. Accordingly, it is believed that Ag⁺ ions at the DOL 32 do not play as significant a role in the antimicrobial efficacy of the region 24a.

After the submersion step 140 is completed, a washing step 160 can be conducted in certain aspects of the method 100 to remove material from the bath 40 remaining on the surfaces of glass article 10, including primary surface 12. Deionized water, for example, can be used in the washing step 160 to remove material from the bath 40 on the surfaces of the glass article 10. Other media may also be employed for washing the surfaces of the glass article 10 provided that the media is selected to avoid any reactions with material from the bath 40 and/or the glass composition of the glass article 10. After completion of the submersion step 140 and the optional washing step 160, the glass article 10 now contains a compressive stress layer 24 and antimicrobial region 24a, thus defining a strengthened, antimicrobial glass article 200.

In certain aspects of the method 100 depicted in FIG. 1, functional coating(s), layer(s) and/or film(s) are applied to a primary surface 12 of the strengthened, antimicrobial glass article 200. For example, the glass article 200 can be coated with a Dow Corning® 2634 fluorosilane abrasion- and fingerprint-resistant coating after completion of the washing step 160. Without being bound by theory, any such functional coating(s), layer(s) and/or film(s) applied to the glass article 10 or glass article 200 during other portions of the method 100 (e.g., before step 120), depending on the temperature resistance of the functional coating(s), layer(s), and/or film(s) to the subsequent steps in the method. As appreciated by those with ordinary skill in the art, the functional coating(s), layer(s) and/or film(s) can be applied at various points in the method 100 depending on process and manufacturing considerations of the strengthened, antimicrobial glass articles 200.

Referring to FIG. 1A, a strengthened, antimicrobial glass article 200 is provided that includes: a glass article 10 comprising a primary surface 12 and a thickness from about 0.5 mm to 2 mm; a compressive stress layer 24 extending from the primary surface 12 of the glass article to a first DOL 22 in the glass article; and an antimicrobial region 24a comprising a plurality of silver ions extending from the primary surface 12 to a second DOL 32 in the glass article. The primary surface 12 of the glass article has a concentration of silver ions that ranges from about 2 mol % to about 20 mol % and the compressive stress layer 24 is characterized by a peak compressive stress of 700 MPa or greater. Further, the antimicrobial region 24a comprises an antimicrobial property at the primary surface characterized by a log kill of 2 or greater for S. aureus bacteria as tested under a Dry Test Protocol. Such articles 200 depicted in FIG. 1A can be fabricated according to the method 100 outlined in FIG. 1.

Referring to FIGS. 1 and 1A, the antimicrobial activity and efficacy obtained in the strengthened, antimicrobial glass article 200 (e.g., as obtained from the method 100) can be quite high. The antimicrobial activity and efficacy can be measured in accordance with Japanese Industrial Standard JIS Z 2801 (2000), entitled “Antimicrobial Products Test for Antimicrobial Activity and Efficacy,” the content of which is hereby incorporated by reference in its entirety as if fully set forth below. Under the “wet” conditions of this test (i.e., about 37° C. and greater than 90% humidity for about 24 hours), strengthened, antimicrobial glass articles fabricated according to the methods described herein can exhibit at least a five log reduction (i.e., LR>˜5) in the concentration (or a kill rate of 99.999%) of at least Staphylococcus aureus, Enterobacter aerogenes, and Pseudomonas aeruginosa bacteria. According to certain implementations of the method 100, it is believed that the strengthened, antimicrobial glass articles 200 can exhibit at least a six log reduction, seven log reduction, or even an eight log reduction (i.e., LR>˜6, ˜7, or ˜8), and all values therebetween, in the concentration of at least Staphylococcus aureus, Enterobacter aerogenes, and Pseudomonas aeruginosa bacteria. Without being bound by theory, it is believed that these antimicrobial efficacy levels as measured by the JIS Z 2801 (2000) test can also be obtained on strengthened, antimicrobial glass articles 200 with a functional coating, layer or file (e.g., a scratch-resistant coating, a fingerprint-resistant coating, and/or a smudge-resistant coating) on its primary surfaces.

According to other embodiments, it is believed that strengthened, antimicrobial glass articles 200 depicted in FIGS. 1 and 1A (e.g., as fabricated according to the method 100) described herein can exhibit at least a two log reduction (i.e., LR>˜2) in the concentration (or kill rate of 99%) of at least Staphylococcus aureus, Enterobacter aerogenes, and Pseudomonas aeruginosa bacteria when tested according to the antimicrobial efficacy testing protocols described in U.S. Provisional Patent Application No. 61/908,401 (“US '401”), filed Nov. 25, 2013 (now published as U.S. Pub. No. 2015/0147775), each of which is hereby incorporated by reference in its entirety as if fully set forth below. Without being bound by theory, it is believed that these antimicrobial efficacy levels as measured by the protocol described in US '401 can also be obtained on strengthened, antimicrobial glass articles 200 with a functional coating, layer or file (e.g., a scratch-resistant coating, a fingerprint-resistant coating, and/or a smudge-resistant coating) on its primary surfaces.

In scenarios where the wet testing conditions of JIS Z 2801 (2000) do not reflect actual use conditions for the strengthened, antimicrobial glass articles 200 described herein (e.g., when the glass articles are used in electronic devices, or the like), the antimicrobial activity and efficacy can be measured using “drier” conditions. As used herein, antimicrobial efficacy testing under these drier conditions is referred to as a “Dry Test Protocol.” In particular, the glass articles 200 can be tested between about 23° C. and about 37° C. and at about 38 to 42% humidity for about 24 hours. Specifically, 5 control samples and 5 test samples can be used, wherein each sample has a specific inoculum composition and volume applied thereto, with a sterile coverslip applied to the inoculated samples to ensure uniform spreading on a known surface area. The covered samples can be incubated under the conditions described above, dried for about 6 to about 24 hours, rinsed with a buffer solution, and enumerated by culturing on an agar plate, the last two steps of which are similar to the procedure employed in the JIS Z 2801 test. Using the Dry Test Protocol, strengthened, antimicrobial glass articles 200 fabricated according to the method 100 can exhibit at least a one log reduction (i.e., LR>˜1) in the concentration (or a kill rate of 90%) of at least Staphylococcus aureus, Enterobacter aerogenes, and Pseudomonas aeruginosa bacteria. In other implementations, these glass articles 200 described herein can exhibit at least an ˜1.5 log reduction, ˜2 log reduction, ˜2.5 log reduction, ˜3 log reduction, ˜3.5 log reduction, or ˜4 log reduction, and all values therebetween, in the concentration of at least Staphylococcus aureus, Enterobacter aerogenes, and Pseudomonas aeruginosa bacteria. Further, these antimicrobial efficacy levels as measured by the Dry Test Protocol can also be obtained on strengthened, antimicrobial glass articles 200 with a functional coating, layer or file (e.g., a scratch-resistant coating, a fingerprint-resistant coating, and/or a smudge-resistant coating) on its primary surfaces. For example, ˜1 to ˜2 log reductions in the concentration of at least Staphylococcus aureus, Enterobacter aerogenes, and Pseudomonas aeruginosa bacteria have been measured on strengthened, antimicrobial glass articles 200.

Referring again to FIGS. 1 and 1A, the strengthened, antimicrobial glass articles 200 (e.g., as fabricated according to the method 100) can be characterized according to some aspects of the disclosure with a peak compressive stress (“CS”) in the compressive stress layer 24 of 500 MPa or greater. In certain aspects, the peak CS in the compressive stress layer 24 of the glass articles 200 is 550 MPa or greater, 600 MPa or greater, 650 MPa or greater, 700 MPa or greater, 750 MPa or greater, 800 MPa or greater, 850 MPa or greater, 900 MPa or greater, 950 MPa or greater, up to 1000 MPa or greater, and all values therebetween. In preferred aspects, the compressive stress layer 24 exhibits a peak CS of 600 MPa or greater. As evidenced by these peak CS levels, the strengthened, antimicrobial glass articles 200 according to aspects of the disclosure can be characterized by average 4-point bend strength levels of 300 MPa or greater, 350 MPa or greater, 400 MPa or greater, 450 MPa or greater, 500 MPa or greater, 550 MPa or greater, 600 MPa or greater, 650 MPa or greater, 700 MPa or greater, and all values therebetween.

Compressive stress is measured by surface stress meter (FSM) using commercially available instruments such as the FSM-6000, manufactured by Orihara Industrial Co., Ltd. (Japan). Surface stress measurements rely upon the accurate measurement of the stress optical coefficient (SOC), which is related to the birefringence of the glass. SOC in turn is measured according to Procedure C (Glass Disc Method) described in ASTM standard C770-16, entitled “Standard Test Method for Measurement of Glass Stress-Optical Coefficient,” the contents of which are incorporated herein by reference in their entirety.

As used herein, DOL means the depth at which the stress in the chemically strengthened glass article described herein changes from compressive to tensile. DOL may be measured by FSM or a scattered light polariscope (SCALP) depending on the ion exchange treatment. Where the stress in the glass article is generated by exchanging potassium ions into the glass article, FSM is used to measure DOL. Where the stress is generated by exchanging sodium ions into the glass article, SCALP is used to measure DOL. Where the stress in the glass article is generated by exchanging both potassium and sodium ions into the glass, the DOL is measured by SCALP, since it is believed the exchange depth of sodium indicates the DOL and the exchange depth of potassium ions indicates a change in the magnitude of the compressive stress (but not the change in stress from compressive to tensile); the exchange depth of potassium ions in such glass articles is measured by FSM.

More generally, the strengthened, antimicrobial glass articles 200 depicted in FIGS. 1 and 1A (e.g., as fabricated according to the method 100) described herein have exceptional antimicrobial properties with enhanced strength levels consistent with or higher than that exhibited by ion exchanged glasses such as Corning® Gorilla® glass. These glass articles 200 also are produced according to the method 100 at a relatively low cost due to the shallow levels of Ag⁺ ions imparted in the articles 200 at step 140 given the relatively low temperatures of the second molten salt bath 40 and/or short duration of the immersion of the article in the bath 40. Another benefit of the DIOX nature of the method 100 is that the strength enhancement and antimicrobial properties can be obtained in the glass articles 200 in only two steps, resulting in lower processing and manufacturing costs. In comparison, conventional approaches often require three or more immersion steps with three or more molten salt baths to achieve comparable (or inferior) strength and antimicrobial efficacy levels in glass articles having the same or similar compositions. A further advantage of glass articles 200 produced according to method 100 is their improved optical properties (or lack of any significant optical property degradation) relative to conventional antimicrobial glasses by virtue of their lower amounts of Ag⁺ ions contained at the primary surfaces of these articles.

As noted earlier, strengthened, antimicrobial glass articles 200 can be fabricated according to the method 100 outlined in the foregoing description. These articles 200 may also be fabricated according to protocols that are modified consistent with the method 100 as outlined in the foregoing. As will also be appreciated by those with ordinary skill in the art, the characteristics of the strengthened, antimicrobial glass articles 200 can also be obtained from variants of method 100, e.g., methods which may contain additional immersion steps and/or other treatments of the primary surface(s) 12 to enhance the peak stress, bend strength, drop resistance, optical properties and/or antimicrobial efficacy of the resulting strengthened, antimicrobial glass articles 200.

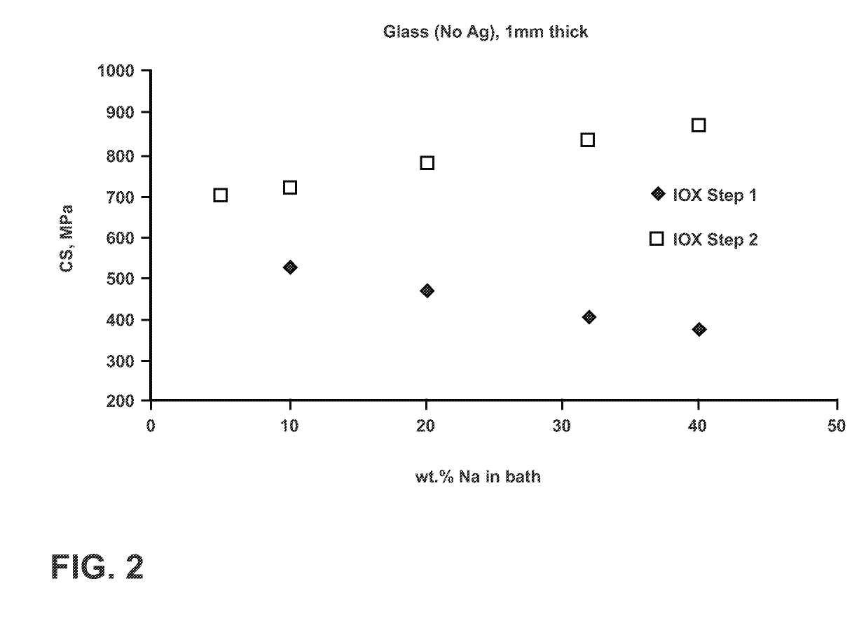

Referring to FIG. 2, a plot of compressive stress measurements obtained on strengthened glass articles as a function of sodium ion concentration in a first molten salt bath taken before and after a second molten salt bath immersion with potassium ions is provided according to an aspect of the disclosure. In FIG. 2, the first molten salt bath had 95 to 60 wt. % KNO₃ and, respectively, 5 to 40 wt. % NaNO₃. The first molten salt bath immersion was conducted at 450° C. for 7.5 hours. The second molten salt bath consisted of approximately 100% KNO₃ and the immersion was conducted at 390° C. for 15 minutes. As shown in FIG. 2, the CS levels measured in the glass articles indicated by “IOX Step 1” were taken after the articles were immersed in the first molten salt bath (before immersion in the second molten salt bath). The CS levels measured in the glass articles indicated by “IOX Step 2” were taken after the articles were immersed in the second molten salt bath. Further, the CS decreases in the glass articles as the poisoning levels (i.e., Na⁺ ions) are increased in the first molten salt bath, indicative of relatively lower amounts of K⁺ ions being incorporated into the glass articles. Conversely, the CS levels measured after the second molten salt bath immersion increase as a function of increasing poisoning levels from the first bath—e.g., up to nearly 900 MPa for a poisoning level of 40 wt. % NaNO₃ in the first molten salt bath. As such, the addition of the poisoning ions into the articles during the first molten salt bath immersion facilitates the introduction of higher levels of K⁺ ions during the second molten salt bath immersion step.

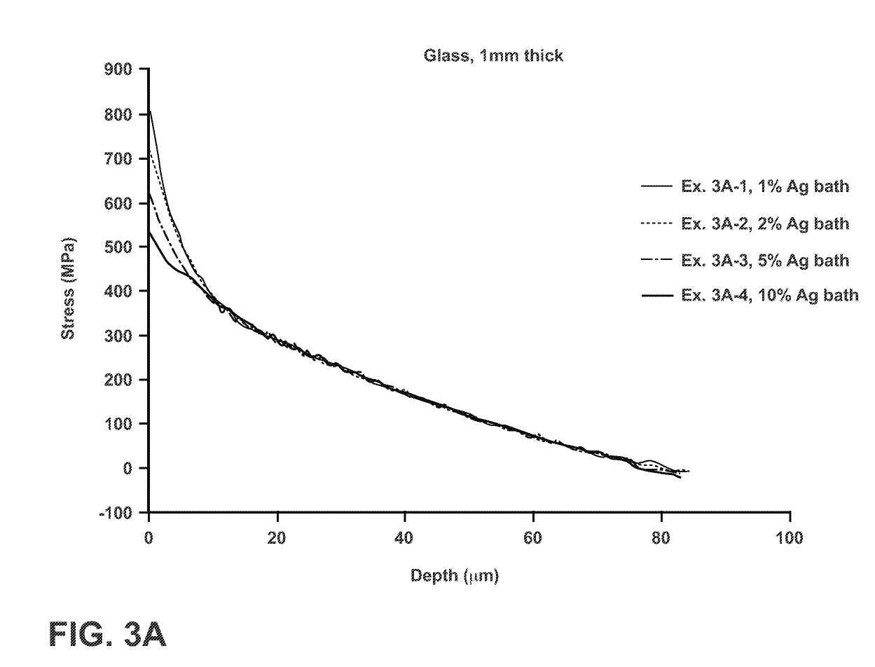

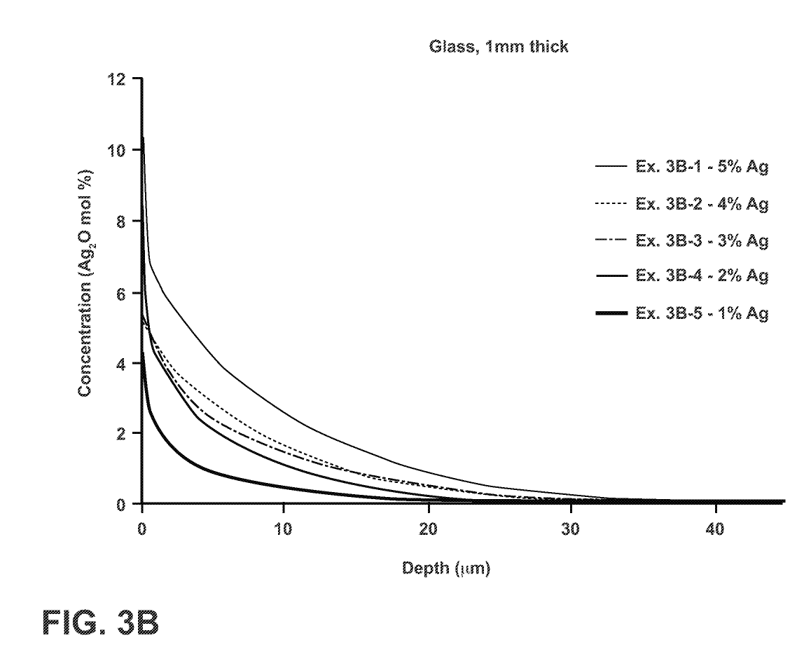

Referring now to FIG. 3A, a plot of compressive stress measurements as a function of depth (microns) obtained on glass articles subjected to various Ag⁺ ion concentrations in a second molten salt bath immersion step according to an aspect of the disclosure. The compressive stress measurements depicted in FIG. 3A were take on strengthened, antimicrobial glass articles fabricated in a manner consistent with method 100 as outlined in the disclosure. In particular, these glass articles had a nominal composition of 60 mol % SiO₂, 17 mol % Al₂O₃, 17 mol % Na₂O, 3 mol % MgO and 6.5 mol % P₂O₅, a thickness of about 1 mm and were subjected to a first immersion step in a first molten salt bath comprising 60 wt. % KNO₃/40 wt. % NaNO₃ at 450° C. for about 7.5 hours. These glass articles were further subjected to a second immersion step in a second molten salt bath comprising 1 to 10 wt. % AgNO₃ and a balance of KNO₃ at 390° C. for 15 minutes. As demonstrated by FIG. 3A, CS levels between about 810 and 530 MPa were obtained for glass articles subjected to a second immersion step in a 1 wt. %, 2 wt. %, 5 wt. % and 10 wt. % AgNO₃ molten salt bath, respectively. It is evident from FIG. 3A that some loss in CS occurs for increasing higher levels of AgNO3 contained in the second molten salt bath. Moreover, CS levels decrease as a function of increasing depth within the glass articles.

Referring now to FIG. 3B, a plot of Ag⁺ ion concentration as a function of depth in glass articles subjected to various Ag⁺ ion concentrations in a second molten salt bath immersion step is provided according to an aspect of the disclosure. The Ag⁺ ion concentration measurements depicted in FIG. 3B were take on strengthened, antimicrobial glass articles fabricated in a manner consistent with method 100 as outlined in the disclosure. In particular, these glass articles had the same composition as the glass shown in FIG. 3A, a thickness of about 1 mm and were subjected to a first immersion step in a first molten salt bath comprising 60 wt. % KNO₃/40 wt. % NaNO₃ at 450° C. for about 7.5 hours. These glass articles were further subjected to a second immersion step in a second molten salt bath comprising 1 to 5 wt. % AgNO₃ and a balance of KNO₃ at 390° C. for 15 minutes. The Ag⁺ ion concentration level data (in mol %) presented in FIG. 3B are derived from glow discharge optical emission spectroscopy (“GD-OES”) testing. As demonstrated by FIG. 3B, the depth of Ag⁺ ion concentration increases with increasing levels of AgNO₃ levels contained in the second molten salt bath. Further, the Ag⁺ ion concentration levels are highest at the surface of the glass articles, ranging from about 4 mol % to about 10 mol % for the glass articles subjected to 1 wt. %, 2 wt. %, 3 wt. %, 4 wt. % and 5 wt. % AgNO₃ in the second molten salt bath.

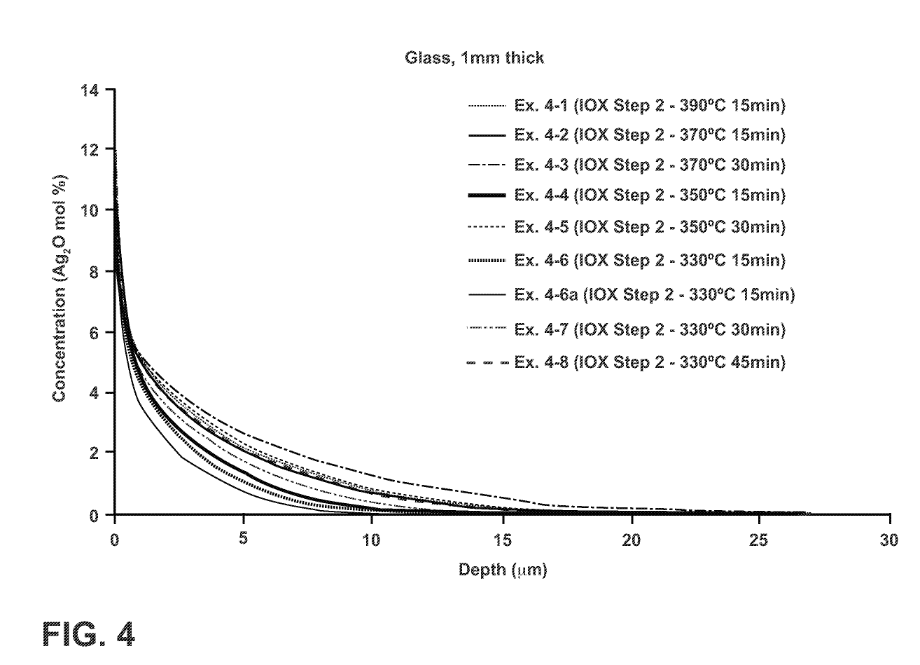

Referring to FIG. 4, is a plot of Ag⁺ ion concentration as a function of depth in glass articles subjected to various second molten salt bath immersion step time and temperature conditions is provided according to an aspect of the disclosure. The Ag⁺ ion concentration measurements depicted in FIG. 4 were taken on strengthened, antimicrobial glass articles fabricated in a manner consistent with method 100 as outlined in the disclosure. In particular, these glass articles had the same composition as the glass shown in FIG. 3A, a thickness of about 1 mm and were subjected to a first immersion step in a first molten salt bath comprising 60 wt. % KNO₃/40 wt. % NaNO₃ at 450° C. for about 7.5 hours. These glass articles were further subjected to a second immersion step in a second molten salt bath comprising 3 wt. % AgNO₃ and a balance of KNO₃ at 330° C. for 15, 30 and 45 minutes, 350° C. for 15 and 30 minutes, 370° C. for 15 and 30 minutes, and 390° C. for 15 minutes. The Ag⁺ ion concentration level data (in mol %) presented in FIG. 4 are derived from GD-OES testing techniques. As demonstrated by FIG. 4, the depth of Ag⁺ ion concentration increases with increasing second bath immersion temperatures and times. Conversely, shorter immersion times and temperatures (e.g., 330° C. for 15 minutes) produce a shallower Ag⁺ ion depth profile with relatively high Ag⁺ ion concentrations at the surface and a DOL (e.g., a second DOL 32 in the glass article 200) of about 10 to 15 microns.

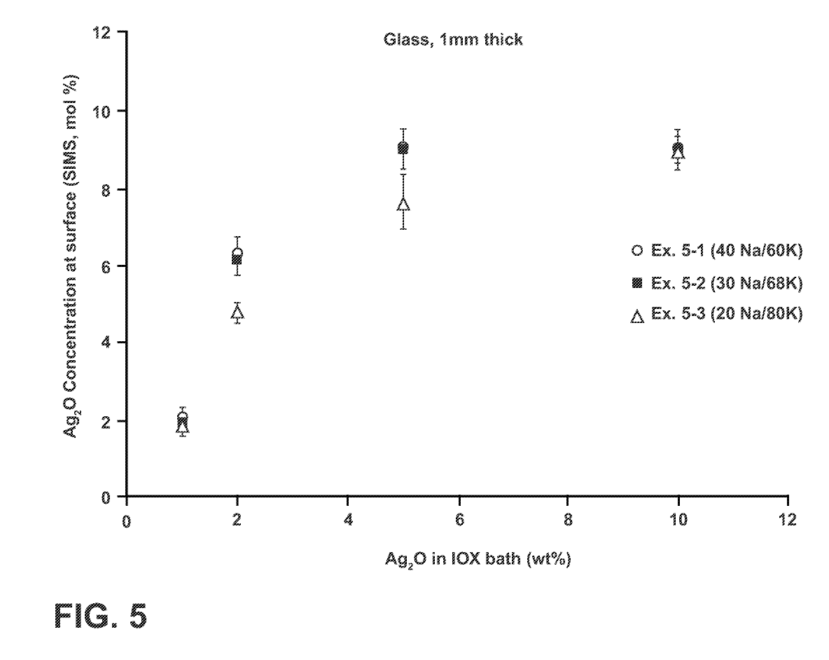

Referring to FIG. 5, a plot of Ag⁺ ion surface concentration as a function of Ag⁺ ion bath concentration for glass articles subjected to various first and second molten salt bath compositions in respective first and second molten salt immersion steps is provided according to an aspect of the disclosure. The Ag⁺ ion concentration measurements depicted in FIG. 5 were taken on strengthened, antimicrobial glass articles fabricated in a manner consistent with method 100 as outlined in the disclosure. In particular, these glass articles had the same composition as the glass shown in FIG. 3A, a thickness of about 1 mm and were subjected to a first immersion step in a first molten salt bath comprising 60 wt. % KNO₃/40 wt. % NaNO₃ (Ex. 5-1); 68 wt. % KNO₃/32 wt. % NaNO₃ (Ex. 5-2); or 80 wt. % KNO₃/20 wt. % NaNO₃ (Ex. 5-3) at 450° C. for about 7.5 hours. These glass articles were further subjected to a second immersion step in a second molten salt bath comprising 1 wt. %, 2 wt. %, 5 wt. % or 10 wt. % AgNO₃ and a balance of KNO₃ at 390° C. for 15 minutes. The Ag⁺ ion surface concentration level data (in mol %) presented in FIG. 5 are derived from secondary ion mass spectroscopy (“SIMS”) testing techniques. As shown in FIG. 5, the Ag⁺ ion surface concentration increases as concentration of Ag⁺ ions in the second molten salt bath is increased. Nevertheless, little increase is observed in the Ag⁺ ion surface concentration for increases in the concentration of the Ag⁺ ions in the second molten salt bath of greater than 5 wt. % AgNO₃. Further, it also appears from the results depicted in FIG. 5 that changes in the composition of the first molten salt bath (i.e., between Exs. 5-1, 5-2 and 5-3) have little impact on the Ag⁺ ion surface concentration.

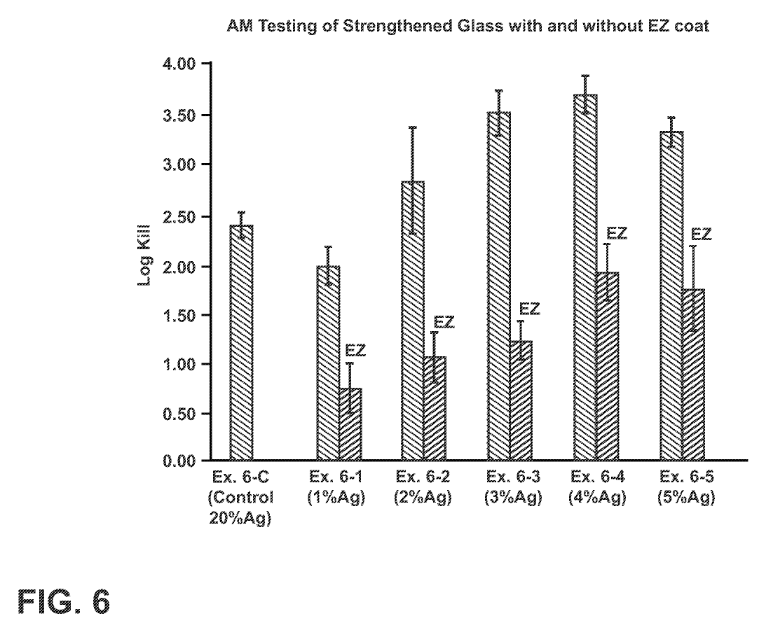

Referring to FIG. 6, a plot depicting the results from antimicrobial testing of strengthened, antimicrobial glass articles, with and without a fingerprint-resistant surface coating, subjected to various Ag⁺ ion concentrations in a second molten salt bath immersion step is provided according to an aspect of the disclosure. The antimicrobial efficacy levels related to log reductions of Staphylococcus aureus in depicted in FIG. 6 were obtained by testing of strengthened, antimicrobial glass article samples according to the Dry Test Protocol, as fabricated in a manner consistent with method 100 as outlined in the disclosure. In particular, these glass articles had the same composition as the glass shown in FIG. 3A, a thickness of about 1 mm and were subjected to a first immersion step in a first molten salt bath comprising 60 wt. % KNO₃/40 wt. % NaNO₃ at 450° C. for about 7.5 hours. These glass articles were further subjected to a second immersion step in a second molten salt bath comprising 1 to 5 wt. % AgNO₃ and a balance of KNO₃ at 390° C. for 15 minutes. A set of each of the sample groups was coated with a Dow Corning® 2634 fluorosilane coating prior to antimicrobial efficacy testing (i.e., “EZ” denotes glass articles having the coating and “No EZ” denotes glass article shaving no fluorosilane functional coating). In addition, a control glass article sample having an alkali aluminosilicate composition (i.e., a composition comparable to the glass shown in FIG. 3A) subjected to immersion in a molten salt bath with 20 wt. % AgNO₃ is also included in the set of results depicted in FIG. 6. As demonstrated by FIG. 6, log kill reductions of from about 2 to 3.7 were observed in the samples tested without a functional, fluorosilane coating, all generally consistent with the control sample. In addition, FIG. 6 demonstrates that log kill reductions between about 0.7 and 1.9 were observed in the same groups, as coated with a functional, fluorosilane coating. As such, those samples fabricated with a second immersion step in a second molten salt bath containing 4 to 5 wt. % AgNO₃ exhibited a log kill reduction comparable to the control, which lacked a functional coating.

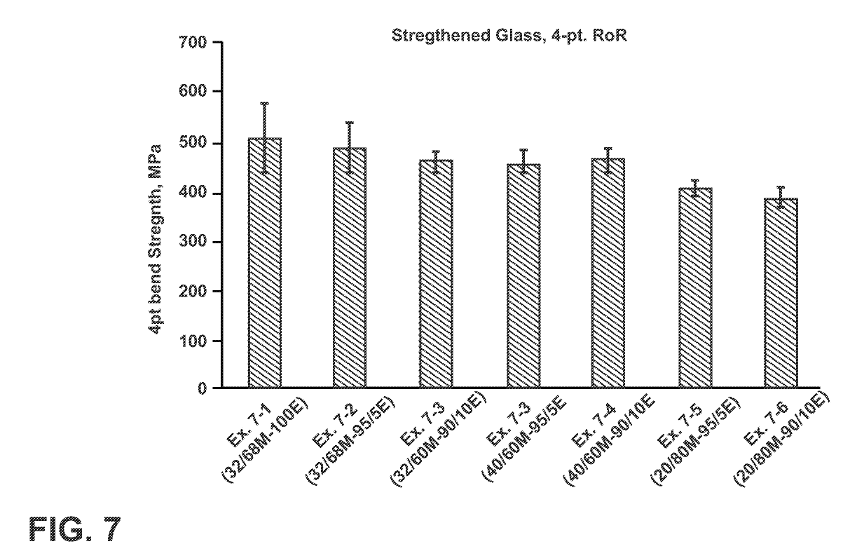

Referring to FIG. 7, a plot of four-point bend strength values from strengthened, antimicrobial glass articles subjected to various first and second molten salt bath compositions is provided according to an aspect of the disclosure. The four-point strength measurements depicted in FIG. 7 were taken on strengthened, antimicrobial glass articles fabricated in a manner consistent with method 100 as outlined in the disclosure. In particular, these glass articles had the same composition as the glass shown in FIG. 3A, a thickness of about 1 mm and were subjected to a first immersion step in a first molten salt bath comprising 60 wt. % KNO₃/40 wt. % NaNO₃; 68 wt. % KNO₃/32 wt. % NaNO₃; or 80 wt. % KNO₃/20 wt. % NaNO₃ at 450° C. for about 7.5 hours. These glass articles were further subjected to a second immersion step in a second molten salt bath comprising 0 wt. % (as a control), 5 wt. % or 10 wt. % AgNO₃ and a balance of KNO₃ at 390° C. for 15 minutes. As shown in FIG. 7, all of the sample groups of strengthened, antimicrobial glass articles processed with varying first and second molten salt bath compositions exhibited strength levels between about 380 MPa and 400 MPa, all comparable to the control group which lacked any Ag⁺ ions.

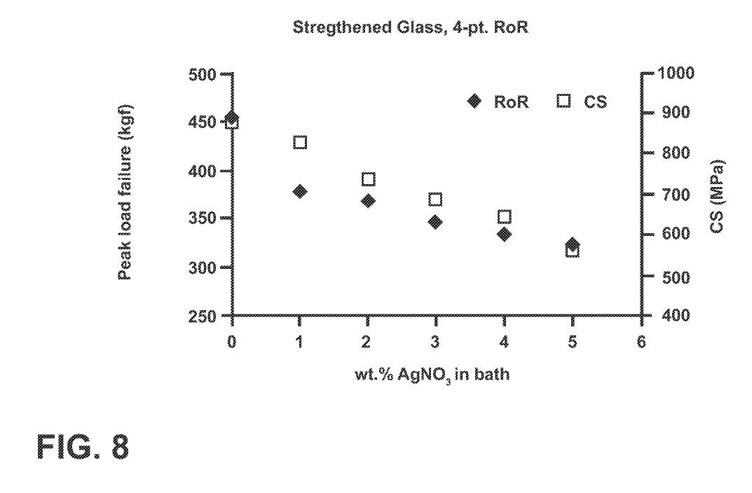

Now referring to FIG. 8, a plot of peak load failure and compressive stress values for glass articles as a function of Ag⁺ ion bath concentration in a second molten salt bath is provided according to an aspect of the disclosure. The mechanical property measurements depicted in FIG. 8 were taken on strengthened, antimicrobial glass articles fabricated in a manner consistent with method 100 as outlined in the disclosure. In particular, these glass articles had the same composition as the glass shown in FIG. 3A, a thickness of about 1 mm and were subjected to a first immersion step in a first molten salt bath comprising 60 wt. % KNO₃/40 wt. % NaNO₃ at 450° C. for about 7.5 hours. These glass articles were further subjected to a second immersion step in a second molten salt bath comprising 1 to 5 wt. % AgNO₃ and a balance of KNO₃ at 390° C. for 15 minutes. As shown in FIG. 8, both peak load to failure (kgf) and peak compressive stress CS (MPa) decreased as the concentration of Ag⁺ ions increased in the second molten salt bath. For those glass articles processed with a second molten bath containing 4 wt. % AgNO₃ or less, CS levels of 600 MPa or greater were observed.

As shown below in Table One, strengthened, antimicrobial glass articles processed comparably to those depicted in FIG. 8 exhibit high levels of antimicrobial efficacy. In particular, these glass articles had the same composition as the glass shown in FIG. 3A, a thickness of about 1 mm and were subjected to a first immersion step in a first molten salt bath comprising 60 wt. % KNO₃/40 wt. % NaNO₃ at 450° C. for about 7.5 hours. These glass articles were further subjected to a second immersion step in a second molten salt bath comprising 1 to 5 wt. % AgNO₃ and a balance of KNO₃ at 390° C. for 15 minutes. All of the samples depicted in Table 1 exhibit a log kill of 5 or greater for testing conducted according to the JIS Z 2801 (2000) method and a log kill of 1.7 to 3.3 for testing conducted according to the Dry Test Protocol. Also of note, CS levels of 561 MPa to 829 MPa were also observed in these glass articles. Accordingly, these strengthened, antimicrobial glass articles exhibit a combination of strength and antimicrobial efficacy.

TABLE ONE

| 2^{nd} molten salt | Dry Test Protocol - no | JIS Z 2801 - no EZ | CS |
|---|---|---|---|
| bath | EZ coating (log kill) | coating (log kill) | (MPa) |
| 1 wt. % AgNO₃ | 1.69 | >5 | 829 |
| 2 wt. % AgNO₃ | 2.67 | >5 | 737 |
| 3 wt. % AgNO₃ | 3.28 | >5 | 687 |
| 4 wt. % AgNO₃ | 3.32 | >5 | 645 |
| 5 wt. % AgNO₃ | 3.12 | >5 | 561 |

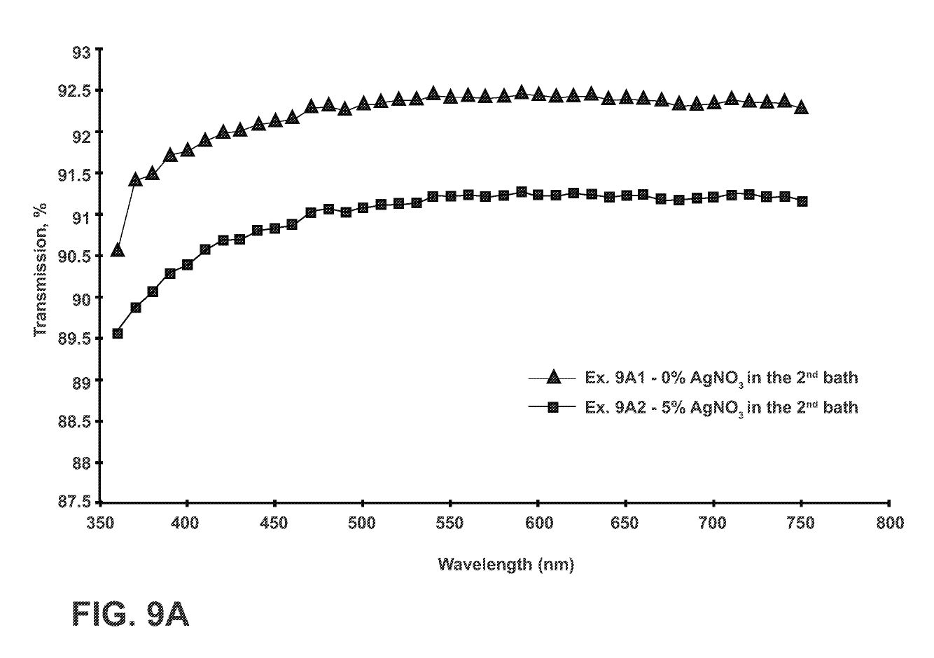

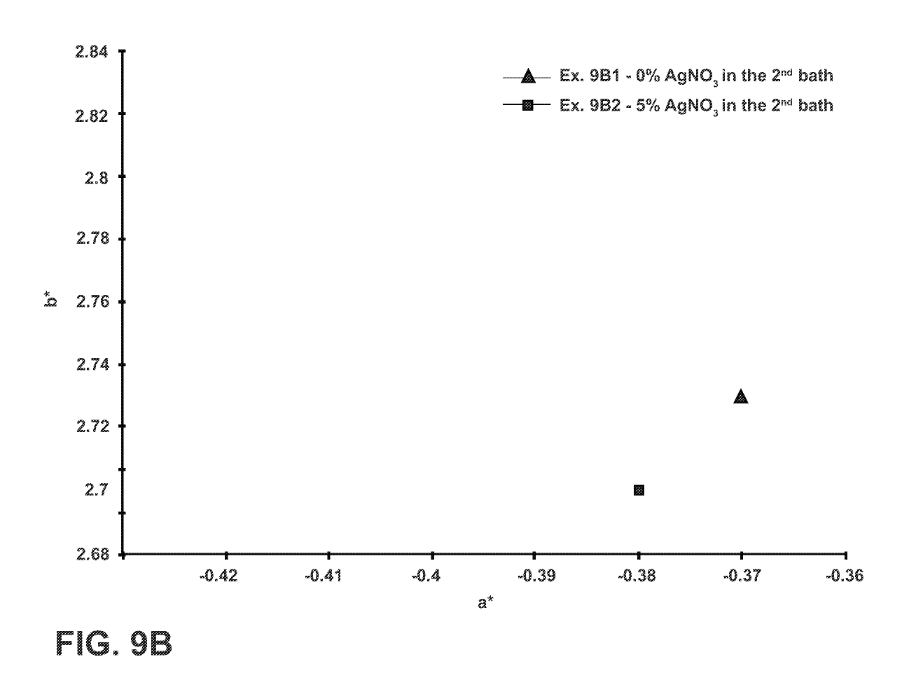

Referring to FIG. 9A, a plot of optical transmissivity as a function of wavelength is provided for strengthened, antimicrobial glass articles as a function of Ag⁺ ion bath concentration in a second molten salt bath according to an aspect of the disclosure. The optical transmissivity measurements depicted in FIG. 9A were taken on strengthened, antimicrobial glass articles fabricated in a manner consistent with method 100 as outlined in the disclosure. In particular, these glass articles had the same composition as the glass shown in FIG. 3A, a thickness of about 1 mm and were subjected to a first immersion step in a first molten salt bath comprising 80 wt. % KNO₃/20 wt. % NaNO₃ at 450° C. for about 7.5 hours. These glass articles were further subjected to a second immersion step in a second molten salt bath comprising 0 wt. % (as a control) (Ex. 9A1) or 5 wt. % (Ex. 9A2) AgNO₃ and a balance of KNO₃ at 390° C. for 15 minutes. As shown in FIG. 9A, a minimal decrease of about 1% in optical transmissivity is observed between the glass articles subjected to a 2^{nd} molten salt bath immersion in a bath containing 5% AgNO₃ (Ex. 9A2) and no AgNO₃ (Ex. 9A1) in the visible spectrum.

Referring to FIG. 9B, a plot of the a* and b* color parameters as measured from exposure to a D65 illumination source for strengthened, antimicrobial glass articles as a function of Ag⁺ ion bath concentration in a second molten salt bath according to an aspect of the disclosure. The color coordinate measurements depicted in FIG. 9B were taken on strengthened, antimicrobial glass articles fabricated in a manner consistent with method 100 as outlined in the disclosure. In particular, these glass articles had the same composition as the glass shown in FIG. 3A, a thickness of about 1 mm and were subjected to a first immersion step in a first molten salt bath comprising 80 wt. % KNO₃/20 wt. % NaNO₃ at 450° C. for about 7.5 hours. These glass articles were further subjected to a second immersion step in a second molten salt bath comprising 0 wt. % (as a control) (Ex. 9B1) or 5 wt % (Ex. 9B2) AgNO₃ and a balance of KNO₃ at 390° C. for 15 minutes. As shown in FIG. 9B, a minimal change in the a* and b* color coordinates of about 0.01 and 0.04, respectively, is observed upon exposure to a D65 illuminant between the glass articles subjected to a 2^{nd} molten salt bath immersion in a bath containing 5% AgNO₃ (Ex. 9B2) and no AgNO₃ (Ex. 9B1).

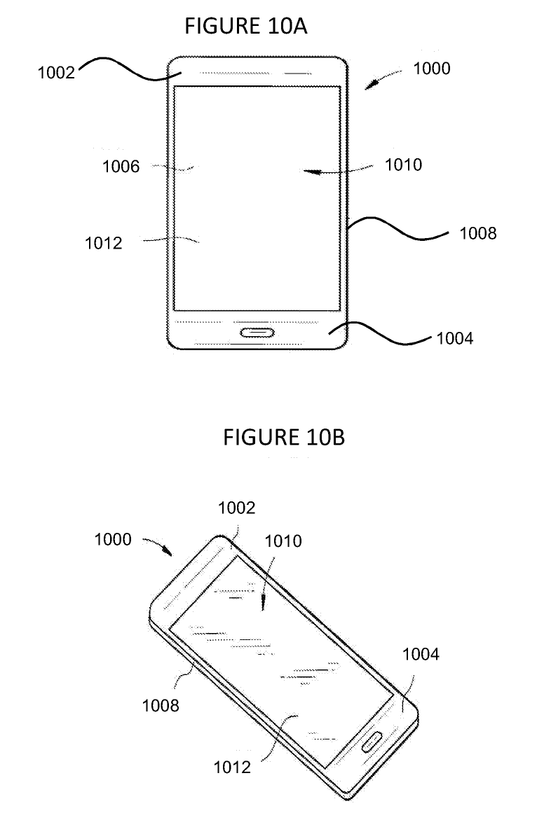

The strengthened, antimicrobial glass articles 200 disclosed herein may be incorporated into another article such as an article with a display (or display articles) (e.g., consumer electronics, including mobile phones, tablets, computers, navigation systems, and the like), architectural articles, transportation articles (e.g., automotive, trains, aircraft, sea craft, etc.), appliance articles, or any article that requires some transparency, scratch-resistance, abrasion resistance or a combination thereof. An exemplary article incorporating any of strengthened, antimicrobial glass articles disclosed herein is shown in FIGS. 10A and 10B. Specifically, FIGS. 10A and 10B shows a consumer electronic device 1000 including a housing 1002 having front 1004, back 1006, and side surfaces 1008; electrical components (not shown) that are at least partially inside or entirely within the housing and including at least a controller, a memory, and a display 1010 at or adjacent to the front surface of the housing; and a cover substrate 1012 at or over the front surface of the housing such that it is over the display. In some embodiments, the cover substrate 1012 may include any of the strengthened, antimicrobial glass articles disclosed herein.

While the embodiments disclosed herein have been set forth for the purpose of illustration, the foregoing description should not be deemed to be a limitation on the scope of the disclosure or the appended claims. It will be apparent to those skilled in the art that various modifications and variations can be made without departing from the spirit or scope of the claims.

What is claimed is:

1. A method of making a strengthened, antimicrobial glass article, comprising the steps:
providing a glass article comprising a primary surface and a plurality of ion-exchangeable alkali metal ions;
providing a first molten salt bath comprising a mixture of ion-exchanging alkali metal ions, the mixture having about 60 to 95 wt. % alkali metal ions that are larger in size than the ion-exchangeable alkali metal ions;
providing a second molten salt bath comprising a mixture of ion-exchanging alkali metal ions and about 1 to 10 wt. % silver ions;
submersing the glass article in the first bath to exchange a portion of the plurality of ion-exchangeable alkali metal ions in the glass article with a portion of the mixture of ion-exchanging alkali metal ions in the first bath to define a compressive stress layer extending from the primary surface to a depth-of-layer (DOL) in the glass article; and
submersing the glass article in the second bath to exchange a portion of the alkali metal ions in the compressive stress layer with a portion of the silver ions in the second bath to impart an antimicrobial property at the primary surface of the glass article.

2. The method according to claim 1, wherein the first molten salt bath comprises a mixture of about 60 to 95 wt. % KNO₃ and a balance of NaNO₃.

3. The method according to claim 2, wherein the second molten salt bath comprises a mixture of KNO₃ and 1 to 10 wt. % AgNO₃.

4. The method according to claim 3, wherein the submersing the glass article in the first bath is conducted for a duration between about 3 hours and 16 hours with the first bath held between about 390° C. and about 470° C.

5. The method according to claim 4, wherein the submersing the glass article in the second bath is conducted for a duration between about 5 minutes and 60 minutes with the second bath held between about 325° C. and about 400° C.

6. The method according to claim 4, wherein the DOL is about 70 μm or greater in the glass article.

7. The method according to claim 6, wherein the compressive stress layer is characterized by a peak compressive stress of 700 MPa or greater.

8. The method according to claim 5, wherein the antimicrobial property comprises a log kill of 1.5 or greater for S. aureus bacteria as tested under a Dry Test Protocol.

9. The method according to claim 5, wherein the antimicrobial property comprises a log kill of 1.5 or greater for S. aureus bacteria as tested under a Dry Test Protocol after deposition of a fingerprint- or smudge-resistant coating on the primary surface of the glass article.

10. The method according to claim 5, wherein the second molten salt bath comprises a mixture of KNO₃ and 2 to 5 wt. % AgNO₃, and further wherein the antimicrobial property comprises a log kill of 2.5 or greater for S. aureus bacteria as tested under a Dry Test Protocol.

11. A strengthened, antimicrobial glass article, comprising:
a glass article comprising a primary surface and a thickness from about 0.5 mm to 2 mm;
a compressive stress layer extending from the primary surface of the glass article to a first depth-of-layer (DOL) in the glass article; and
an antimicrobial region comprising a plurality of silver ions extending from the primary surface to a second DOL in the glass article,
wherein the primary surface of the glass article has a concentration of silver ions that ranges from about 2 mol % to about 20 mol % and the compressive stress layer is characterized by a peak compressive stress of 700 MPa or greater, and
further wherein the antimicrobial region comprises an antimicrobial property at the primary surface characterized by a log kill of 2 or greater for S. aureus bacteria as tested under a Dry Test Protocol.

12. The article according to claim 11, wherein the primary surface of the glass article has a concentration of silver ions that ranges from about 4 mol % to about 15 mol %.

13. The article according to claim 11, wherein the first DOL is about 70 μm or greater in the glass article.

14. The article according to claim 11, wherein the antimicrobial region comprises an antimicrobial property at the primary surface characterized by a log kill of 2.5 or greater for S. aureus bacteria as tested under a Dry Test Protocol.

15. The article according to claim 11, wherein the antimicrobial region comprises an antimicrobial property at the primary surface characterized by a log kill of 3.0 or greater for S. aureus bacteria as tested under a Dry Test Protocol.

16. The article according to claim 11, wherein the antimicrobial region comprises an antimicrobial property in proximity to the primary surface characterized by a log kill of 2 or greater for S. aureus bacteria as tested under a Dry Test Protocol after deposition of a fingerprint- or smudge-resistant coating on the primary surface of the glass article.

17. A method of making a strengthened, antimicrobial glass article, comprising the steps:
providing a glass article comprising a primary surface and a plurality of ion-exchangeable alkali metal ions;
providing a first molten salt bath comprising a mixture of ion-exchanging alkali metal ions between about 420° C. and about 460° C., the mixture having about 60 to 95 wt. % K⁺ ions and a balance of Na⁺ ions;
providing a second molten salt bath comprising a mixture of about 1 to 10 wt. % Ag⁺ ions and a balance of K⁺ ions between about 325° C. and about 400° C.;
submersing the glass article in the first bath for about 5 hours to 10 hours to exchange a portion of the plurality of ion-exchangeable alkali metal ions in the glass article with a portion of the mixture of K⁺ and Na⁺ ions in the first bath to define a compressive stress layer extending from the primary surface to a depth-of-layer (DOL) in the glass article; and
submersing the glass article in the second bath for about 5 minutes and 60 minutes to exchange a portion of the alkali metal ions in the compressive stress layer with a portion of the Ag⁺ ions in the second bath to impart an antimicrobial property at the primary surface of the glass article,
wherein the antimicrobial property comprises a log kill of 1.5 or greater for S. aureus bacteria as tested under a Dry Test Protocol, and
further wherein the compressive stress layer is characterized by a peak compressive stress of 600 MPa or greater.

18. The method according to claim 17, wherein the mixture of ion-exchanging alkali metal ions of the first molten salt bath is set at about 450° C. and the mixture of about 1 to 10 wt. % Ag⁺ ions and a balance of K⁺ ions of the second molten salt bath is set between 3.80° C. and 400° C.

19. The method according to claim 18, wherein the second molten salt bath comprises a mixture of about 1 to 5 wt. % Ag⁺ ions and a balance of K⁺ ions and the compressive stress layer is characterized by a peak compressive stress of 700 MPa or greater.

20. The method according to claim 19, wherein the antimicrobial property comprises a log kill of 2.5 or greater for S. aureus bacteria as tested under a Dry Test Protocol.

21. A device comprising:
a housing having front, back, and side surfaces;
electrical components that are at least partially inside the housing;
a display at or adjacent to the front surface of the housing; and
a cover substrate disposed over the display, wherein the cover substrate comprises the strengthened, antimicrobial glass article of claim 11.
